(19) United States
(12) Patent Application Publication
(10) Pub. No.: US 2026/0191002 A1
(43) Pub. Date: Jul. 2, 2026

(54) METHOD OF MANUFACTURING SEMICONDUCTOR DEVICES AND CORRESPONDING SEMICONDUCTOR DEVICE

(71) Applicant: STMicroelectronics International N.V., Geneva (CH)

(72) Inventors: Reiner Alvaran MAGHIRANG, Bouskoura (MA); Oussama BELAARIF, Casablanca (MA)

(73) Assignee: STMicroelectronics International N.V., Geneva (CH)

(21) Appl. No.: 19/428,745

(22) Filed: Dec. 22, 2025

(30) Foreign Application Priority Data
Dec. 27, 2024 (IT) 102024000030051

(51) Int. Cl. H10W 42/00; H10W 72/00; H10W 72/30; H10W 90/00

(52) U.S. Cl. CPC H10W 42/121; H10W 72/01351; H10W 72/07334; H10W 72/332; H10W 72/334; H10W 90/734

(57) ABSTRACT

A semiconductor die is arranged on a surface of a solder material provided at a die mounting region of a substrate. A portion of the surface of the solder material is left uncovered by the semiconductor die. A pattern of cavities is formed at the portion of the surface of the solder material left uncovered by the semiconductor die. An electrically insulating encapsulation is molded onto the semiconductor die arranged at the die mounting region of the substrate. The electrically insulating encapsulation contacts the portion of the surface of the solder material having the cavities. The pattern of cavities counters delamination of the electrically insulating encapsulation with respect to the solder material provided at the die mounting region of the substrate.

### PRIORITY CLAIM

This application claims the priority benefit of Italian Application for Patent No. 102024000030051 filed on Dec. 27, 2024, the content of which is hereby incorporated by reference in its entirety to the maximum extent allowable by law.

### TECHNICAL FIELD

The description relates to semiconductor devices.

One or more embodiments can be applied to integrated circuit semiconductor devices for automotive and/or industrial application.

### BACKGROUND

In current manufacturing processes of semiconductor devices, a protective plastic package is provided by molding an electrically insulating molding compound onto a semiconductor die (or chip) arranged on a substrate.

The plastic package protects the (integrated circuit (IC)) semiconductor die from humidity and/or contaminants that could otherwise damage the die, possibly causing failure of the device.

A common issue in such devices is connected to the undesired delamination of the package from the substrate; a relatively poor adhesion of the electrically insulating molding compound to the substrate may undesirably result in detachment (delamination) of the package from the substrate.

More in detail, it has been observed that delamination of the package may develop at the interface between the electrically insulating encapsulating material of the package and the solder material provided at the surface of the substrate to facilitate attaching a semiconductor die to the substrate.

Reference is made to United States Patent Publication Nos. 2020/0135602 A1, 2020/0402895 A1, 2024/0038682 A1, 2024/0128143 A1 and 2024/0014152 A1, all of which are incorporated herein by reference, which provide background information in the related technological area.

There is a need in the art to overcome the drawbacks discussed in the foregoing.

### SUMMARY

One or more embodiments relate to a method.

One or more embodiments relate to a corresponding (integrated circuit) semiconductor device.

Solutions as described involve arranging a semiconductor die on solder material provided at a die mounting region of a substrate (a leadframe, for instance).

Solutions as described herein comprise forming a pattern of cavities at a region of the surface of the solder material left uncovered by a semiconductor die arranged thereon.

In solutions as described herein, a pattern of cavities may be formed via laser beam energy applied at a region of the surface of the solder material left uncovered by a semiconductor die arranged thereon.

In an embodiment, a method comprises: arranging a semiconductor die on a surface of a solder material provided at a die mounting region of a substrate, wherein a portion of the surface of the solder material is left uncovered by the semiconductor die arranged thereon; forming a pattern of cavities at the portion of the surface of the solder material left uncovered by the semiconductor die arranged thereon; and molding an electrically insulating encapsulation onto the semiconductor die arranged at the corresponding die mounting region of the substrate, wherein the electrically insulating encapsulation contacts the portion of the surface of the solder material having said cavities thereon, wherein the pattern of cavities counter delamination of the electrically insulating encapsulation with respect to the solder material provided at the die mounting region of the substrate.

In an embodiment, a device comprises: a semiconductor die arranged on a surface of a solder material provided at a die mounting region of a substrate, wherein a portion of the surface of the solder material is left uncovered by the semiconductor die arranged thereon; a pattern of cavities formed at the portion of the surface of the solder material left uncovered by the semiconductor die arranged thereon; and an electrically insulating encapsulation molded encapsulating the semiconductor die arranged at the corresponding die mounting region of the substrate, wherein the electrically insulating encapsulation contacts the portion of the surface of the solder material having said cavities thereon, wherein the pattern of cavities counter delamination of the electrically insulating encapsulation with respect to the solder material provided at the die mounting region of the substrate.

### BRIEF DESCRIPTION OF THE DRAWINGS

One or more embodiments will now be described, by way of example only, with reference to the annexed figures, wherein:

FIGS. 1 and 2 are a plan view and a cross-section view (wherein FIG. 2 is a cross-sectional view along line II-II of FIG. 1) illustrative of the structure of a semiconductor device;

FIGS. 3 and 4 are cross-sectional views (wherein FIG. 4 is an enlarged view of the portion of FIG. 3 indicated by the arrow IV) illustrative of details of a semiconductor device;

FIG. 5 is a plan view illustrative of details of a semiconductor device obtainable via processing steps as described herein; and

FIG. 6 is a block diagram illustrative of a sequence of processing steps.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

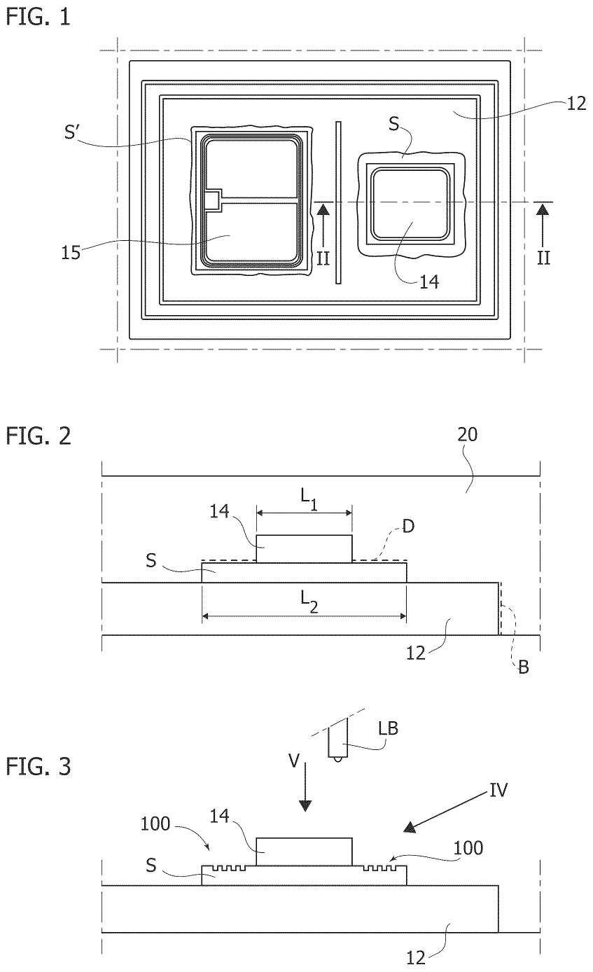

FIG. 1 is a plan view illustrative of the structure of a semiconductor device.

As illustrate, a semiconductor device may comprise: a substrate 12 such a leadframe, for instance, and one or more semiconductor (Si, SiC, GaN) dice 14, 15 arranged at respective die mounting regions of the substrate 12.

The designation “leadframe” (or “lead frame”) is currently used (see, for instance the USPC Consolidated Glossary of the United States Patent and Trademark Office) to indicate a metal frame (copper, for instance) that provides support for an integrated circuit chip or die (the terms chip/chips and die/dice are herein regarded as synonymous) as well as electrical leads to interconnect the integrated circuit in the die or chip to other electrical components or contacts.

Essentially, a leadframe comprises an array of electrically-conductive formations (or leads, not visible in the figures for simplicity) that from an outline location extend inwardly in the direction of a semiconductor chip or die (the terms die/dice and chip/chips are herein regarded as synonymous) thus forming an array of electrically-conductive formations from a die pad configured to have at least one semiconductor chip or die attached thereon.

A leadframe 12 can be of the pre-molded type, that is a type of leadframe comprising a sculptured metal (copper, for instance) structure formed by etching a metal sheet and comprising empty spaces that are filled by a resin “pre-molded” on the sculptured metal structure.

In the exemplary semiconductor device illustrated in FIG. 1, a first semiconductor die 14 and a second semiconductor die 15 are arranged at respective die mounting regions of the substrate 12.

The first semiconductor die 14 may be a driver/controller die configured to drive a power die (such as the second semiconductor die 15, for instance).

As illustrated, solder material S, S′ (tin or a tin alloy, for instance) is provided on the surface of the substrate 12 at the die mounting regions in order to facilitate attaching the die to the substrate. Solder material S, S′ may be provided by dispensing a solder paste at the surface of the substrate 12 or by arranging a solder preform, that is, a block of solder material (comprising also flux, for instance) that is pick-and-placed at the die mounting regions of the substrate 12.

As known to those skilled in the art, a thermal reflow (reflow, for short) step is performed in order to facilitate attachment of the semiconductor die/dice 14, 15 and form a layer of solder material on the copper die pad of the leadframe.

It is noted that the solder material used to attach the first 14 and the second 15 semiconductor die may comprise different solder material; in other words, a first solder material S may be used to facilitate attaching the first semiconductor die 14 with a die attach solder layer and a second solder material S′ may be used to facilitate attaching the second semiconductor die 15 with a die attach solder layer.

Subsequently to attaching the semiconductor dice 14, 15 electrically conductive formations, such as bonding wires, clips, ribbons, etc., are provided in order to provide electrical coupling between the first 14 and the second 15 semiconductor die and/or between the semiconductor dice 14, 15 and the substrate 12 (electrically coupling the semiconductor dice 14, 15 to selected leads of the substrate 12, for instance).

An electrically insulating encapsulation is thus provided to the device by molding an electrically insulating molding compound (an epoxy resin, for instance) onto the substrate 12 having the semiconductor die or dice 14, 15 attached thereon.

FIG. 2 is a cross-sectional view along line II-II of FIG. 1 illustrative of a semiconductor device as described in the foregoing provided with an electrically insulating encapsulation 20.

As illustrated, the electrically insulating molding compound of the encapsulation 20 contacts the layer of solder material S at the region indicated by the dashed line D, that is, the portion of the top/front surface of the solder material S that is left uncovered by the semiconductor die 14 arranged on the solder material S. It has been observed that delamination (that is, detachment) of the encapsulation 20 is likely to occur at the interface D between the encapsulation 20 and the layer of solder material S (or S′) due to a relatively poor adhesion of the encapsulation 20 to the solder material S, S′.

Delamination may further develop, possibly reaching the semiconductor die/dice 14, 15 or the back/bottom surface of the device (for instance, at points B of the interface between the substrate 12 and the encapsulation 20) increasing the risk of humidity and/or contaminants to enter the encapsulation 20 and reach the semiconductor die/dice 14, 15.

Such delamination may undesirably result in failure and/or rejection of the device.

Moreover, as mentioned previously, a first S and a second S′ solder materials may be used to attach a first 14 and a second 15 semiconductor dice, respectively, as in the device exemplified in FIG. 1. First S and second S′ solder materials may comprise different materials (for instance, different tin alloys) and/or have different thermal (or electrical) properties, tailored to the thermal and/or mechanical and/or electrical specifications of the respective semiconductor die. Different solder materials may involve different reflow steps, that is, different types of reflow as well as different reflow temperature and/or temperature profile.

When more than one reflow step is performed, the surface of the solder material S, S′ may be altered in such a way to further reduce adhesion with the electrically insulating encapsulation 20 that is subsequently molded.

It is noted that in certain semiconductor devices (in power devices, for instance) having solder material provided on a region of the substrate 12 having an area larger than the semiconductor die may be advantageous in so far as this facilitates controlling the bond line thickness (BLT), and/or facilitates forming a fillet having a desired height.

Solutions as described involve arranging a semiconductor die on solder material provided at a die mounting region of a substrate (a leadframe, for instance).

Solutions as described herein comprise forming a pattern of cavities at a region of the surface of the solder material left uncovered by a semiconductor die arranged thereon.

In solutions as described herein, a pattern of cavities may be formed via laser beam energy applied at a region of the surface of the layer of solder material left uncovered by a semiconductor die arranged thereon.

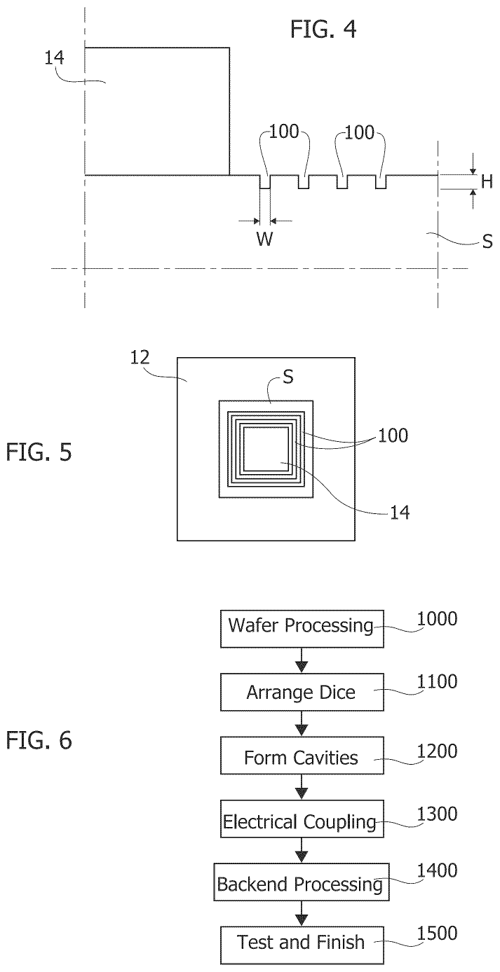

FIGS. 3 and 4 are cross-sectional views (wherein FIG. 4 is an enlarged view of the portion of FIG. 3 indicated by the arrow IV) illustrative of a semiconductor device processed according to embodiments of the present description.

It is noted that in current manufacturing processes of semiconductor devices, plural devices may be manufactured concurrently to be separated into single individual device in a final singulation.

For simplicity and ease of explanation, the following description will refer to manufacturing a single device.

The following description will refer to a single semiconductor die 14 arranged at a corresponding die mounting region of a substrate 12 being otherwise understood that solutions as described in the following may be applied also in devices comprising more than one semiconductor die arranged on a substrate.

As illustrated in FIG. 3, a semiconductor die 14 is arranged at a corresponding die mounting region of a substrate 12 (a die pad in a leadframe, for instance). Attachment of the semiconductor die 14 is facilitated by a layer of solder material S provided at the die mounting region.

As mentioned in the foregoing, solder material S may be provided at the die mounting region(s) of the substrate by: dispensing a solder paste at said at least one die mounting region of the substrate 12, and/or arranging a solder preform at the die mounting region of the substrate 12.

Subsequent to arranging the semiconductor die 14 on the solder material S, the assembly may be processed via a reflow step in order to form the solder joint, comprising a layer of solder material, between the semiconductor die 14 and the substrate 12.

As illustrated, the semiconductor die 14 arranged on a first region of the layer of solder material S, and this leaves a second region of the top/front surface of the layer of solder material S uncovered.

In one or more embodiments, cavities 100 are formed at the second region of the surface of the layer of solder material S that is left uncovered by the semiconductor die 14.

Advantageously, cavities 100 may be formed, for example as trenches, via laser beam energy LB applied to the region of the top/front surface of the layer of solder material S left uncovered by the semiconductor die 14, that is by partially (and selectively) removing (ablating) solder material at the top/front surface of the layer of solder material S to form the cavities 100.

Referring to FIG. 4, a plurality of cavities 100 may be formed with a cavity depth H and a cavity width W. The cavity depth H is preferably less than a thickness of the layer of solder material.

In one or more embodiments, the cavity depth H may be comprised in the range between 20 microns and 70 microns, preferably between 35 microns and 55 microns.

In one or more embodiments, the cavity width W may be comprised in the range between 10 microns and 80 microns, preferably between 30 microns and 60 microns.

FIG. 5 is a plan view illustrative of a semiconductor as exemplified in FIG. 4 illustrated in the direction of view indicated by the arrow V of FIG. 4.

In embodiments as illustrated in FIG. 5, the semiconductor die 14 is arranged at a central region of the layer of solder material S provided at the die mounting region of the substrate 12. A peripheral region around the central region is thus left exposed, that is left uncovered by the semiconductor die 14 arranged on the layer of solder material S. In such embodiments, cavities 100 are thus formed at the peripheral region of the solder material left uncovered by the semiconductor die 14.

As illustrated, cavities 100 may be formed as trenches having trench lengths, perpendicular to both the width W and depth H, extending along parallel lines sidewise of the semiconductor die 14 arranged on the solder material S—for example having the trench length be parallel to an adjacent side edge of the die. In an embodiment, each cavity 100 is formed by a trench having a ring shape surrounding the die.

Of course, the pattern of trenches (or grooves) for the cavities 100 illustrated in FIG. 5 is merely exemplary of a possible pattern; patterns of cavities 100 using trenches other than the one exemplified in FIG. 5 are also possible.

Further processing of an assembly as illustrated in FIGS. 4 to 5 may comprise per se conventional processing steps.

For instance, electrically conductive formations (wires, for instance) may be provided extending between the top/front surface of the semiconductor die 14, 15 to selected pads of the substrate 12 (outer pads such as the leads in a leadframe, for instance).

Subsequently, an electrically conductive encapsulation 20 is provided by molding an electrically insulating molding material (an epoxy resin, for instance) onto the assembly.

The electrically insulating encapsulation 20 contacts the portion of the surface of the solder material S, S′ having the pattern of cavities 100 formed thereon.

The pattern of cavities 100 enhances adhesion of the electrically insulating encapsulation 20 to the surface of the solder material S, S′ in contact therewith.

The electrically insulating molding compound may fill (or at least partially fill) the cavity 100, thus providing an anchoring point to the electrically insulating encapsulation 20 molded onto the assembly.

In summary, solutions as described herein comprise arranging at least one semiconductor die 14, 15 on a surface of a layer of solder material S, S′ provided at a surface of at least one die mounting region of a substrate 12, wherein a portion of a surface of the solder material S, S′ is left uncovered by the at least one semiconductor die 14, 15 arranged thereon.

Subsequently, a pattern of cavities 100 is formed at the portion of the surface of the layer of solder material S, S′ left uncovered by the at least one semiconductor die 14, 15 arranged thereon.

An electrically insulating encapsulation 20 is molded onto the at least one semiconductor die 14, 15 arranged at the corresponding at least one die mounting region of the substrate 12.

The electrically insulating encapsulation 20 contacts the portion of the surface of the solder material S, S′ having the cavities 100 thereon. More specifically, the material of the electrically insulating encapsulation 20 enters and at least partially fills the cavities to provide anchoring portions.

The pattern of cavities 100 counters delamination of the electrically insulating encapsulation 20 with respect to the solder material S, S′ provided at the at least one die mounting region of the substrate 12.

Advantageously, laser beam energy LB may be applied to the portion of the surface of the solder material left uncovered by the at least one semiconductor die 14, 15 arranged thereon to form therein the pattern of cavities 100.

Advantageously, the at least one semiconductor die 14, 15 arranged on the surface of the solder material S, S′ provided at the corresponding at least one die mounting region of the substrate 12 may be processed via a reflow step. The pattern of cavities 100 may be formed at the portion of the surface of the solder material left uncovered by the at least one semiconductor die 14, 15 arranged thereon subsequently to said reflow step.

The person skilled in the art may appreciate how solutions as described herein may be easily implemented in an (otherwise conventional) assembly flow.

An assembly flow comprising processing steps as described in the foregoing is illustrated in the block diagram of FIG. 6.

It will be otherwise appreciated that the sequence of steps illustrated in FIG. 6 is merely exemplary insofar as: one or more steps illustrated in FIG. 6 can be omitted, performed in a different manner (with other tools, for instance) and/or replaced by other steps; additional steps may be added; and one or more steps can be carried out in a sequence different from the sequence illustrated.

The sequence of steps exemplified in FIG. 6 comprises:
Step 1000: wafer level processing steps, such as providing one or more integrated circuits (ICs) in a semiconductor (Si, SiC, GaN, for instance) wafer, dicing the semiconductor wafer to obtains a plurality of semiconductor dice (such as the semiconductor dice 14 or 15);
Step 1100: arranging one or more semiconductor dice 14, 15 onto solder material S, S′ provided at die mounting region(s) of a substrate (a leadframe, for instance);
Step 1200: forming a pattern of cavities 100 at the region of the surface of the solder material S, S′ left uncovered by the semiconductor die 14, 15 arranged thereon;
Step 1300: providing electrical coupling (via wire bonding, for instance) between the semiconductor die 14, 15 and selected pads (leads, for instance) of the substrate 12;
Step 1400: further processing the assembly via per se conventional backend processing steps (molding and/or singulating, for instance);
Step 1500: optionally, testing and finishing.

Devices processed according to solutions as described herein have an electrically insulating package less prone to delamination, at the cost of a relatively simple processing step.

Without prejudice to the underlying principles, the details and the embodiments may vary, even significantly, with respect to what has been described by way of example only without departing from the scope of the embodiments.

The claims are an integral part of the technical teaching provided in respect of the embodiments.

The extent of protection is determined by the annexed claims.

1. A method, comprising:
arranging a semiconductor die on a surface of a layer of solder material provided at a die mounting region of a substrate, wherein a portion of the surface of the layer of solder material is left uncovered by the semiconductor die;
removing portions of solder material from the layer of solder material to form a pattern of cavities extending into the surface of the layer of solder material at the portion left uncovered by the semiconductor die; and
molding an electrically insulating encapsulation onto the semiconductor die arranged at the die mounting region of the substrate, wherein the electrically insulating encapsulation enters said cavities at the portion of the surface of the layer of solder material;
wherein the pattern of cavities is configured to counter delamination of the electrically insulating encapsulation with respect to the solder material provided at the die mounting region of the substrate.

2. The method of claim 1, wherein removing portions of solder material comprises applying laser beam energy to the portion of the surface of the layer of solder material left uncovered by the semiconductor die.

3. The method of claim 1, further comprising providing solder material at said die mounting region of the substrate by dispensing solder paste at said die mounting region of the substrate.

4. The method of claim 1, further comprising providing solder material at said die mounting region of the substrate by arranging a solder preform at said die mounting region of the substrate.

5. The method of claim 1, comprising:
attaching the semiconductor die arranged on the surface of the solder material provided at the die mounting region of the substrate via a solder reflow; and
after the solder reflow, removing portions of solder material to form said pattern of cavities at the portion of the surface of the layer of solder material left uncovered by the semiconductor die.

6. The method of claim 1:
wherein arranging the semiconductor die comprises placing the semiconductor die at a central portion of the layer of solder material provided at the die mounting region of the substrate, wherein the semiconductor die arranged on the layer of solder material leaves uncovered a peripheral portion of the surface of the layer of solder material surrounding said central portion; and
wherein removing portions of solder material to form said pattern of cavities comprises forming the cavities at the peripheral portion of the surface of the layer of solder material left uncovered by the semiconductor die.

7. The method of claim 1, where said cavities comprise trenches.

8. The method of claim 7, wherein the trenches comprise rings surrounding the semiconductor die.

9. The method of claim 1, wherein each cavity has a cavity depth in a range between 20 microns and 70 microns.

10. The method of claim 9, wherein each cavity has a cavity width in a range between 10 microns and 80 microns.

11. A device, comprising:
a semiconductor die on a surface of a layer of solder material at a die mounting region of a substrate, wherein a portion of the surface of the layer of solder material is left uncovered by the semiconductor die;
a pattern of cavities in the surface of the layer of solder material at the portion left uncovered by the semiconductor die; and
an electrically insulating encapsulation that encapsulates the semiconductor die at the die mounting region of the substrate, wherein the electrically insulating encapsulation is within the cavities at the portion of the surface of the layer of solder material, wherein the pattern of cavities are configured to counter delamination of the electrically insulating encapsulation with respect to the layer of solder material at the die mounting region of the substrate.

12. The device of claim 11, wherein the layer of solder material at said die mounting region of the substrate comprises a solder paste located at said die mounting region of the substrate.

13. The device of claim 11, wherein the layer of solder material provided at said die mounting region of the substrate comprises a solder preform located at said die mounting region of the substrate.

14. The device of claim 11:
wherein the semiconductor die is arranged at a central portion of the layer of solder material provided at the die mounting region of the substrate, wherein the semiconductor die arranged on the layer of solder material leaves uncovered a peripheral portion of the surface of the layer of solder material surrounding said central portion, and
wherein said pattern of cavities are located at the peripheral portion of the surface of the layer of solder material.

15. The device of claim 11, wherein each cavity has a cavity depth in a range between 20 microns and 70 microns.

16. The device of claim 15, wherein each cavity has a cavity width in a range between 10 microns and 80 microns.

17. The device of claim 11, where said cavities comprise trenches.

18. The device of claim 17, wherein the trenches comprise rings surrounding the semiconductor die.
